(19) United States
(12) Patent Application Publication
(10) Pub. No.: US 2009/0243644 A1
(43) Pub. Date: Oct. 1, 2009

(54) SOCKET, TEST DEVICE AND TEST METHOD FOR TESTING ELECTRONIC ELEMENT PACKAGES WITH LEADS

(76) Inventor: Chiu-Fang Chang, Taipei (TW)

Correspondence Address: STOUT, UXA, BUYAN & MULLINS LLP, 4 VENTURE, SUITE 300, IRVINE, CA, 92618, US

(21) Appl. No.: 12/142,675

(22) Filed: Jun. 19, 2008

(30) Foreign Application Priority Data
Mar. 28, 2008 (TW) 097111350

(51) Int. Cl. G01R 31/28

(52) U.S. Cl. 324/757

(57) ABSTRACT

The present invention relates to a socket, test device and test method for testing electronic element packages with leads, and particularly relates to a socket, test device and test method for testing image sensors with leads. The test device comprises a socket, a plurality of test probes and a test circuit board. The socket comprises a base having a plurality of first holes, a guiding structure having a plurality of second holes and at least one floating member used to connect the base and the guiding structure. In the socket, test device and test method of the present invention, each test probe is received into one first hole and one second hole to maintain the top surface of guiding structure to be even for preventing the deflective placing of the electronic element packages, and for preventing the damage to the test probes. The test probes are controlled by compressing the floating member for protruding form the top surface of the guiding structure and for providing a shorter delivering path of the electronic signals between the test circuit board and the electronic element packages. This shorter delivering path of the electronic signals can improve the accuracy and reliability of the test process for the electronic element packages with leads.

### BACKGROUND OF THE INVENTION

1. Field of the Invention

A socket, test device and test method for testing electronic element packages with leads, and particularly relates to a socket, test device and test method for testing image sensors with leads.

2. Description of the Prior Art

After the manufacturing process of electronic elements is finished, a circuit probe test is performed to recognize and confirm the quality of the electronic elements for preparing to package the electronic elements. It prevents from the waste of the packaging process which is resulted from packaging the electronic elements with bad quality. Furthermore, a final test is performed to recognize and confirm the packaged electronic elements without any damage and in scale.

A test device and test method for the common packaged electronic elements with leads, for example Quad Flat Package (QFP), is illustrated in FIG. 1A. Referring to FIG. 1A, an electronic element package 10 is placed in a socket 14. The socket 14 has several probes 16 which penetrate through the socket 14 and protrude from the top surface of the socket 14 for contacting and electrically connecting with the leads 12 of the electronic element package 10. Furthermore, probes 16 also protrude from the bottom surface of the socket 14 for contacting and electrically connecting with a test circuit board 18 under the socket 14. Electronic signals are delivered from test circuit board 18 to the electronic element package 10 by a delivering path composed of leads 12, probes 16 and test circuit board 18.

Before the test, the electronic element package 10 needs to be placed in the socket 14 by a common way, for example by throwing or by dropping off in the air. It means that the electronic element package 10 is thrown or dropped off to fall into the socket 14 when the electronic element package 10 is close to the top surface of the socket 14 but there is still a little distance apart the electronic element package 10 from the top surface of the socket 14. However, when the electronic element package 10 is placed in the socket 14, the electronic element package 10 is supported by the tips of the probes 16, but not the surface of the socket 14. It is because that the top tips of the probes 16 protrude from the top surface of the socket 14. The contacting position of probes 16 and the electronic element package 10 may be shifted because the heights of all probes 16 are not absolutely the same or the electronic element package 10 is dropped off deflectively as FIG. 1B showing. Therefore, when the element package 10 is pressed to contact the element package 10 with the probes 16 tightly, a lateral force caused by the shift is performed on the tips of the probes 16 and then the probes 16 is damaged or crooked. It decreases the lifetime of the probes and increases the cost of the test, and furthermore, it decreases the test rate because the probes need to be changed more frequently.

Besides, the test device or the socket, as showed in FIG. 1A, can not be used for testing an image sensor. Although a image sensor is often packaged in the package form without leads, like Ball Grid Array (BGA), but the image sensor is packaged in package form with leads, like QFP, in recent years. However, the test device or the socket showed in FIG. 1A can not be used for testing the image sensor with leads, and the image sensor with leads are tested by the test device or the socket showed in FIG. 2 for the image sensor without leads.

Referring to FIG. 2, a common test device for testing the image sensors is illustrated in it. An image sensor 20 is placed on the socket 28. The light active surface 23 of the image sensor 20 faces downward and the leads 22 of the image sensor 20 faces upward. The socket 28 has an opening aligned with the light active surface 23 for passing the light to the light active surface 23. The socket 28 has several first probe pins 26. The top tips of the first probe pins 26 are protrude from the top surface of the socket 28, and the bottom tips of the first probe pins 26 are protrude from the bottom surface of the socket 28 for electrically connecting with a test circuit board 29. A contact plate 27 is disposed above the socket 28, and the contact plate 27 has several second probe pins 25 for electrically connecting with the leads 22. The first probe pins 26 and the second probe pins 25 are electrically with each other by a signal transfer device 24. In the test device for testing image sensor, a signal delivering path between the test circuit board 29 and the image sensor 20 is formed by the first probe pins 26, the signal transfer device 24 and the second probe pins 25 for delivering the test signals. However, the electronic signals need to pass through the first probe pins 26, the signal transfer device 24 and the second probe pins 25, and then the electronic signals can be delivered to the test circuit board 29 or the image sensor 20. This signal delivering path is too long and need to pass through too many elements so that the contacting capacity increases and the accuracy and the reliability of the test decrease.

For solving the problems of the prior art that the probes of the conventional test device or socket damage during the test, and the signal delivering path is too long and contacting capacity increases, a need has arisen to provide a test device or socket for testing the electronic element packages with leads or the image sensor with leads, which is capable of preventing the probes form damage and crooked, shortening the signal delivering path, decreasing the contacting capacity and improving the accuracy and the reliability of the test.

### SUMMARY OF THE INVENTION

In view of the foregoing, it is an object of the present invention to provide a socket and a test device for testing the electronic element packages with leads, which is capable of preventing the probes form damage and crooked.

Another object of the present invention is to provide a socket and a test device for image sensors with leads, which is capable of preventing the probes form damage and crooked and shortening the signal delivering path.

Still another object of the present invention is to provide a test method for image sensors with leads, which is capable of preventing the probes form damage and crooked and shortening the signal delivering path.

According to the object, one embodiment of the present invention provides a socket and a test device for testing the electronic element packages with leads or the image sensors with leads. The test device or socket comprises a base having a plurality of first holes, a guiding structure for guiding and holding an electronic element package with leads to be tested and at least one floating member disposed between the base and the guiding structure. The guiding structure has a plurality of second holes and each of the second holes is corresponded to one of the first holes. Before testing, each of the test probes is received into one of the first holes and one of the second holes corresponded to the first hole, and each of the test probes does not protrude from the top surface of the guiding structure for preventing the deflective placing of the electronic element packages with leads. When the electronic element package with leads is tested, the floating member is shrunk by compressing for decreasing the height of the guiding structure. By the way, the probes protrude from the top surface of the guiding structure to contact the electronic element package with leads for electrically connecting the test circuit board and the electronic element package with leads and shortening the electronic signal delivering path.

According to the object, one embodiment of the present invention provides a test method for testing the image sensors with leads. First, an image sensor is placed on a guiding structure of a socket, wherein a plurality of test probes received into the guiding structure the said socket. And then, the socket is compressed for protruding the test probes from the top surface of the guiding structure to contact the image sensors with leads. After that, an electronic signal is inputted through the test probes for testing said electronic element package with leads. In the test method, before testing, the test probes are received into the test device or socket for preventing the deflective placing of the image sensor with leads. When the image sensor with leads is tested the floating member is shrunk by compressing for decreasing the height of the guiding structure. By the way, the probes protrude from the top surface of the guiding structure to contact the electronic element package with leads for electrically connecting the test circuit board with the image sensor with leads and forming a shorter electronic signal delivering path.

Therefore, the effect achieved with the present invention, that is not found in prior art, is to provide a socket, test device and a test method for testing the electronic element packages with leads or the image sensors with leads that capable of preventing the deflective placing and damage of the image sensor with leads. It can increase the lifetime of the probes and decrease the times of changing the probes for increases test rate. Furthermore, it can provide a shorter electronic signal delivering path and improving the accuracy and the reliability of the test process.

### BRIEF DESCRIPTION OF THE DRAWINGS

FIG. 1A is a cross-sectional view illustrating a conventional test device for testing the electronic element packages with leads;

FIG. 1B is a cross-sectional view illustrating a conventional test device with a deflective placing of the electronic element packages;

FIG. 2 is a cross-sectional view illustrating a conventional test device for testing the image sensors with leads;

FIG. 3A is a cross-sectional view illustrating a test device for testing the electronic element packages with leads according to one embodiment of the present invention;

FIG. 3B is a cross-sectional view illustrating a test device for testing the electronic element packages with leads according to another embodiment of the present invention;

FIG. 3C is a plane view illustrating a test device for testing the electronic element packages showed in FIG. 3A;

FIG. 4A is a cross-sectional view illustrating a test device for testing the image sensors with leads according to one embodiment of the present invention;

FIG. 4B is a cross-sectional view illustrating a test device for testing the image sensors with leads according to another embodiment of the present invention;

FIG. 5 is a flow chart illustrating a test method for testing the image sensors with leads according to one embodiment of the present invention.

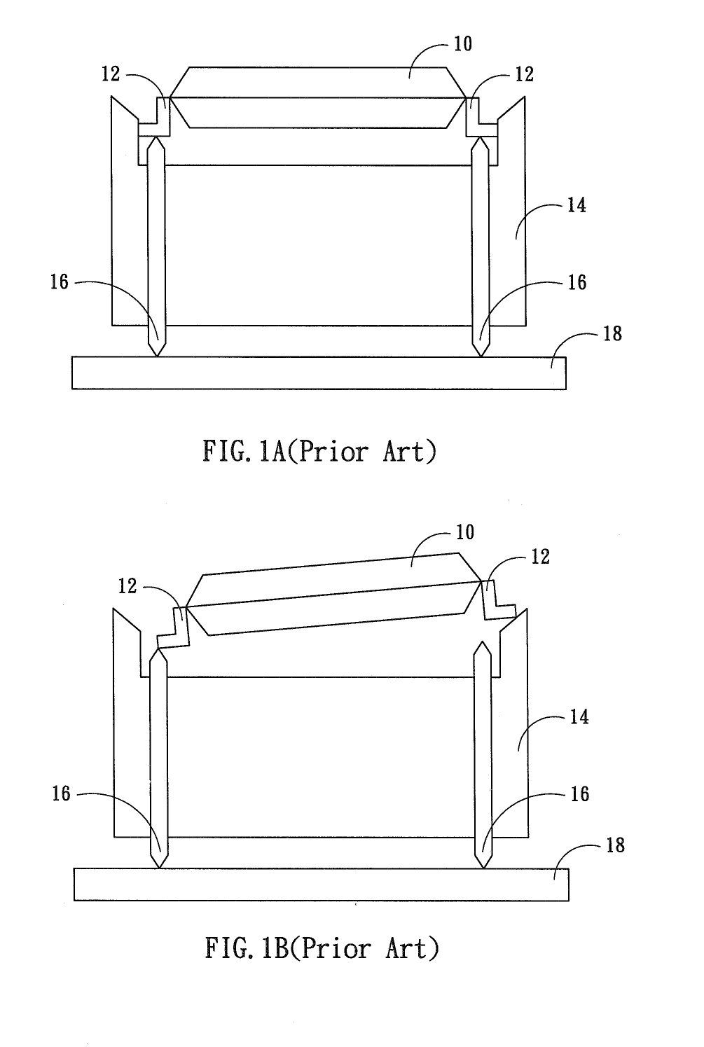

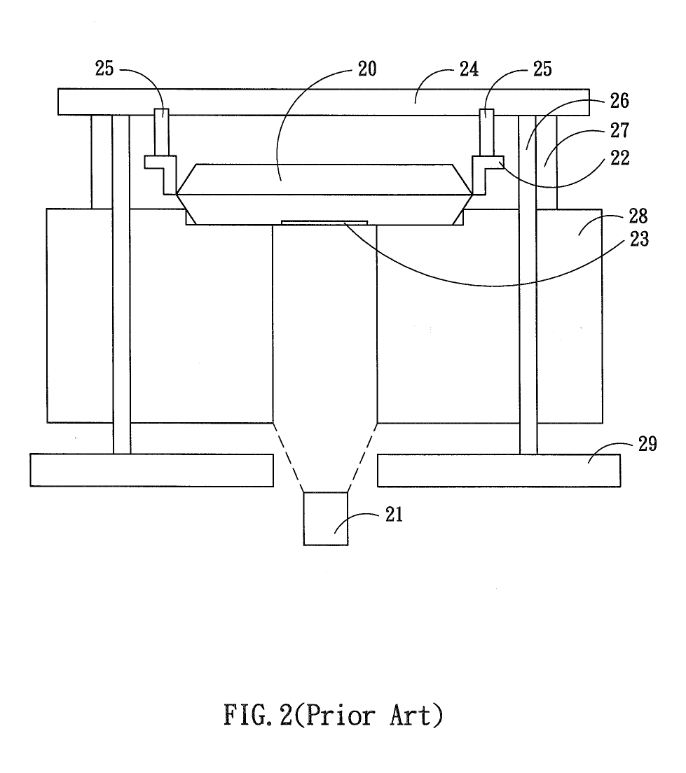

### DETAILED DESCRIPTION OF THE INVENTION

The following is the detailed description of the embodiments of the present invention. It is appreciated that the processes and structures described below do not entirely encompass whole processes and structures. The present invention could be practiced in conjunction with various fabrication techniques, and only the commonly practiced processes are included to provide an understanding of the present invention.

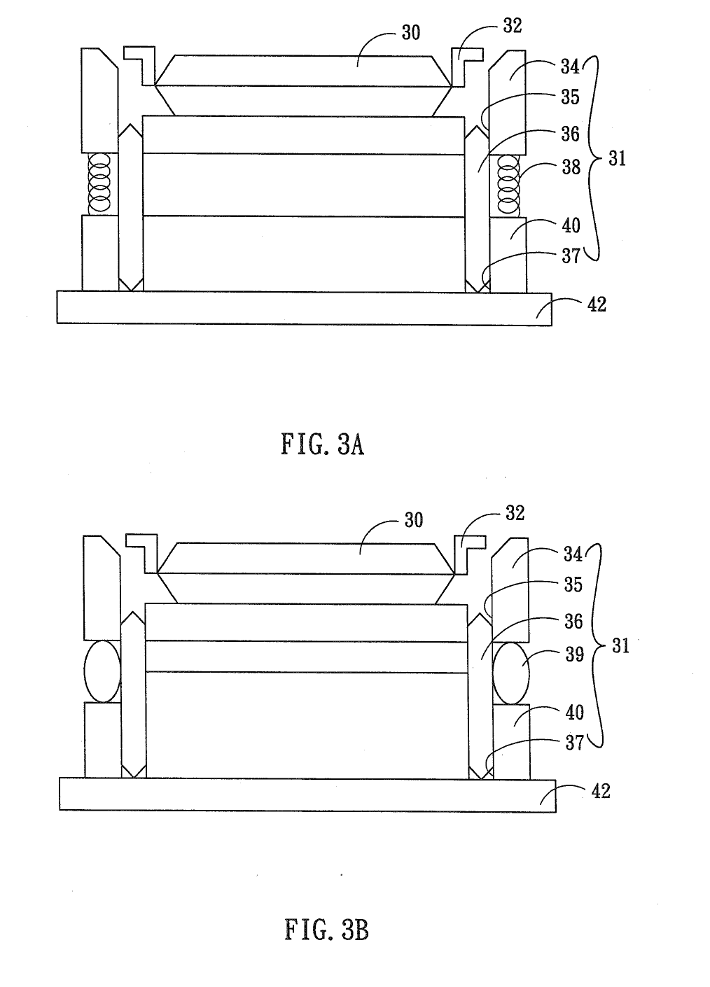

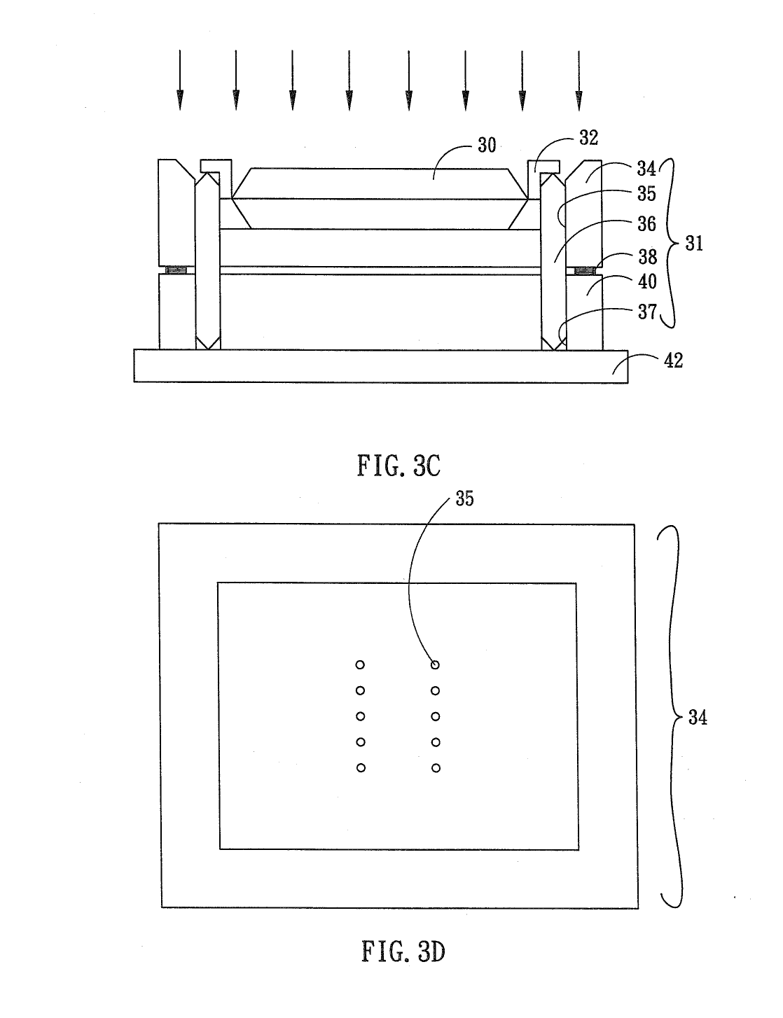

Referring to FIG. 3A, it is a cross-sectional view illustrating a test device for testing the electronic element packages with leads according to one embodiment of the present invention. The test device comprises a socket 31, a plurality of test probes 36 and a test circuit board 42. The socket 31 comprises a base 40 having a plurality of first holes 37, a guiding structure 34 that is used for guiding and holding a electronic element package 30 with leads to be tested has a plurality of second holes 35 (FIG. 3A is a plane view illustrating the guiding structure 34), and at least one or more floating member 38 disposed between the base 40 and the guiding structure 34 for connecting the base 40 with the guiding structure 34. Each of the second holes 35 is corresponded to one of the first holes 37. Each of the first holes 37 penetrates through the base 40, and each of the second holes 35 penetrates through the guiding structure 34. Besides, the guiding structure 34 has a cavity for holding an electronic element package with leads to be tested. The guiding structure 34 “floats” on the base 40. It means that the guiding structure 34 is disposed on the base 40 and connected the base 40 only by the floating member 38, and the guiding structure 34 can move up and down by compressing the floating member 38 for changing the height of the guiding structure 34 in the test device.

In this test device (or socket 31), each of the test probes 36 is received into one of the first holes 37 and one of the second holes 35 corresponded to the first hole 37 before compressing the test device (or socket 31). And thus, before testing, each top tip of the test probes 36 is received into one of the second holes 35. Therefore, each top tip of the test probes 36 does not protrude from the top surface of the guiding structure 34 to maintain the surface of the guiding structure 34 for placing the electronic element package 30 (for example the top surface of the guiding structure 34) to be even. By this way, the deflective placing of the electronic element package 30 can be prevented when the electronic element package 30 is placed in the test device (or the socket 31). When the test device (or the socket 31) is compressed for testing, there is no any lateral force caused by the deflective placing of the electronic element package 30 to perform on the test probe 36, and the test probe 36 will not be damaged and crooked. Besides, before compressing the test device (or the socket 31), each bottom tip of the test probes 36 is at the same level with the bottom surface of the base 40, as FIG. 3A showing, and each bottom tip of the test probes 36 is contacted and electrically connected with the test circuit board 42. However, in another embodiment of the present invention, each top tip of the test probes does not protrude from the top surface of the guiding structure, and each bottom tip of the test probes does not protrude from the bottom surface of the base before compressing the test device (or the socket). And in the embodiment, before compressing the test device (or the socket), each bottom tip of the test probes is not at same level with the bottom surface of the base and is not contacted and electrically connected with the test circuit board. Therefore, the test probes are received into the test device (or the socket) like floating in the test device (or the socket). But in the embodiment, after compressing the test device (or the socket), each bottom tip of the test probes protrudes from the bottom surface of the base and then each bottom tip of the test probes is contacted and electrically connected with the test circuit board. Or in still another embodiment of the present invention, each bottom tip of the test probes protrudes from the bottom surface of the base and is contacted and electrically connected with the test circuit board before compressing the test device (or the socket).

In the test device (or the socket 31), the diameters of the first hole 37 and the second hole 35 is big enough for that the test probes 36 are capable of moving up and down freely, like floating in the test device (or the socket 31). Therefore, the diameters of the first hole 37 and the second hole 35 need not to be limited, and it is not necessary that the diameter of the first hole 37 is the same with the diameters of the second hole 35.

Furthermore, in the test device (or the socket 31), the guiding structure 34 is supported and connected with the base 40 by the floating member 38. The floating member 38 can be shrunk by compressing or the pressure, and the floating member 38 can be restored by releasing the pressure. Therefore, the guiding structure 34 can move up and down in a particular ambit freely by pressing or compressing the test device or the guiding structure 34. By this way, the test probes 36 are controlled to receive in the test device and to protrude and expose form the top surface of the guiding structure 34, and even to be contact and electrically connected with the leads 32. The floating member 38 is a spring as shown in FIG. 3A. Or, in another embodiment of the present invention, the floating member 38 is an elastic material 39 as shown in FIG. 3B. The shape of the elastic material 39 can be an elliptic ball as shown in FIG, 3B, but not limit. In another embodiment of the present invention, the shape of the elastic material can be a ball, a cylinder, a cube, a pillar or a pillar with a plurality corners. The elastic material can be manufactured with any shape according to the design of the test device or the socket. As the test devices (or sockets 31) illustrated in FIG. 3A and FIG. 3B, the floating members 38 are disposed on two sides of the top surface of the base 40, but not limit. In another embodiment, the floating members can be disposed on four sides, a pair of diagonal corners, two a pairs of diagonal corners or the center zone on top surface of the base 40. The floating members can be disposed on any position which is capable of supporting the guiding structure on the base and connecting he guiding structure with the base in the present invention.

In the test devices (or sockets 31) illustrated in FIG. 3A and FIG. 3B, when compressing or pressing the top surface of the test device, the guiding structure 34 or the electronic element package 30 held on the guiding structure 34, the floating member 38 (or 39) is shrunk by the compressing for decreasing the height of the guiding structure in the test device (or socket 31). Therefore, the guiding structure 34 moves down with the electronic element package 30 and the top tips of the test probes protrude from the top surface of the guiding structure 34 through the second holes 35 for contacting and electrically connecting with the leads 32 of the electronic element package 30, as FIG. 3C showing. No matter the bottom tips of the test probe 36 are at the same level with the bottom surface of the base 40, or the bottom tips of the test probe 36 protrude or do not protrude from the bottom surface of the base 40, the bottom tips of the test probe 36 protrude from the bottom surface of the base 40 to contact and electrically connect with the test circuit board 42 or more tightly when compressing or pressing test device (or socket 31). By the way, a shorter electronic signal delivering path is provides. After the test is finished and the pressure on the test device (or socket 31) is removed, the floating member 38 is restored because of the releasing of the pressure and the elastic characteristics of the floating member 38. Therefore, the guiding structure 34 is raised to the original position in the socket 31 before compressing, and then, the top tips of the test probe 36 are separated from the leads 32 and received into the second holes 35. The test probes 36 are received into test device (or the socket 31) again. At the same time, the bottom tips of the test probes 36 come back the original position in the socket 31 before compressing.

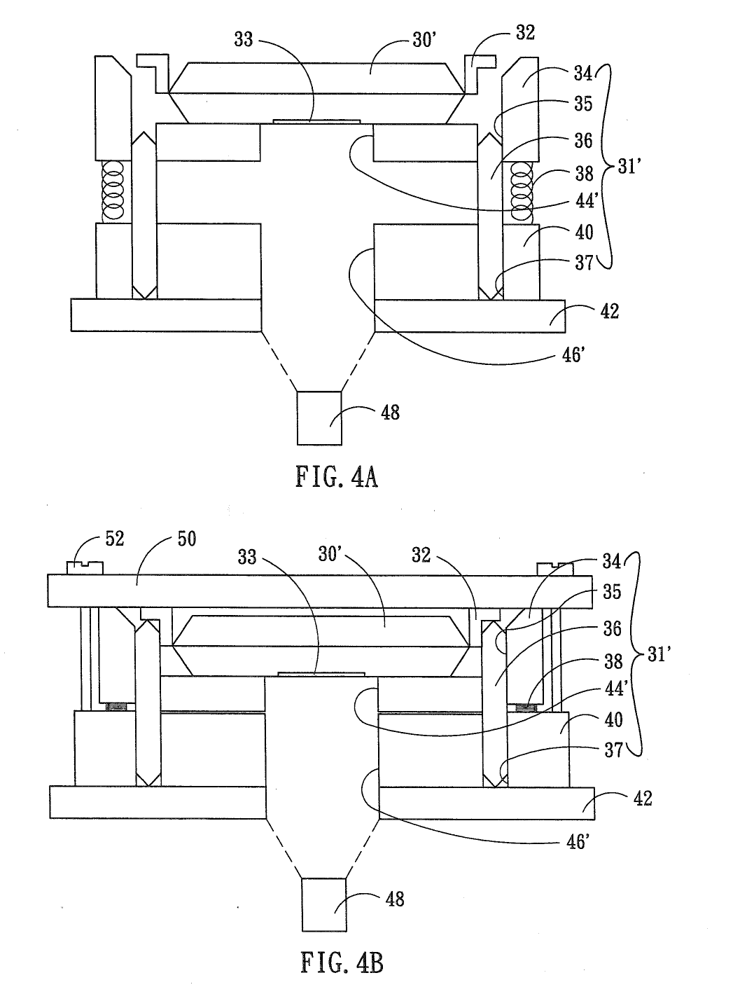

The present invention also provide test device and socket for solving the problems of the prior art about that the test probes are damaged and the electronic signal delivering path is too long in test process for image sensors. Referring to FIG. 4A, it is a cross-sectional view illustrating a test device for testing the image sensors with leads according to one embodiment of the present invention. The test device illustrated in FIG. 4A is almost the same with the test device illustrated in FIG. 3A. The test device illustrated in FIG. 4A also comprises a socket 31′, a plurality of test probes 36′ and a test circuit board 42′. The socket 31′ illustrated in FIG. 4A is almost the same with the socket 31 illustrated in FIG. 3A. The socket 31′ illustrated in FIG. 4A also comprises a base 40 having a plurality of first holes 37, a guiding structure 34 that is used for guiding and holding a electronic element package 30 with leads to be tested has a plurality of second holes 35, and at least one or more floating member 38 disposed between the base 40 and the guiding structure 34 for connecting the base 40 with the guiding structure 34. However, in the socket 31′, the base 40 has a first opening 46, and the guiding structure 34 has a second opening 44 corresponded to the first opening 46 and the light active surface 33 of the image sensor 30′. When a image sensor 30′ is tested, the image sensor 30′ is placed on the cavity disposed on the top surface of the guiding structure 34 and the light active surface 33 faced down. Therefore, the light emitting by the light source 48 is transmitted to the light active surface 33 of the image sensor 30′ through the first opening 46 and the second opening 44 for testing.

Besides, as shown in FIG. 4B, the test device further comprises a pressing plate 50. The pressing plate 50 is disposed above the test device and fixed on the base 40 by screws 52 for pressuring the socket 31′ or the image sensor 30′ on the base 40. Similarly, a pressing plate can be disposed above the test devices illustrated in FIG. 3A and FIG. 3B.

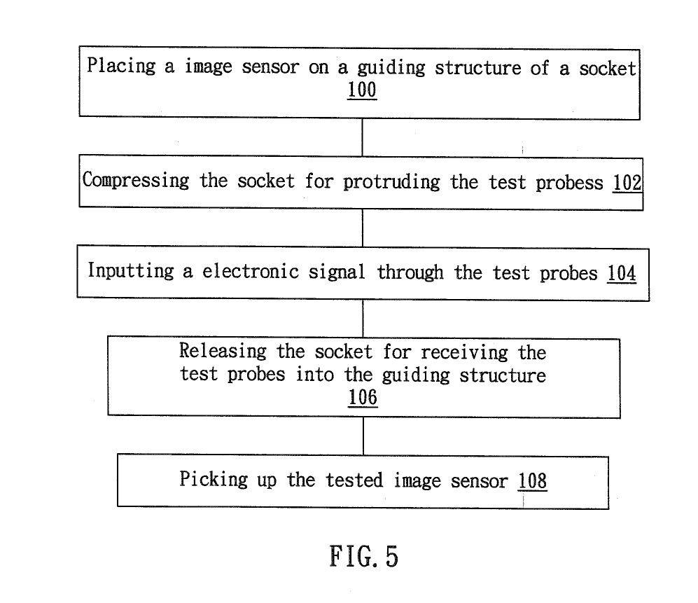

Furthermore, the present invention provides a test method for testing the image sensors with leads. Referring to FIG. 5, it is a flow chart illustrating a test method for testing the image sensors with leads according to one embodiment of the present invention. First, as step 100, an image sensor with leads is placed on a guiding structure of a socket, wherein a plurality of test probes received into the guiding structure the said socket, as the test device (or the socket 31′) illustrated in FIG. 4A or FIG. 4B. And then, the socket 31′ is compressed or the image sensor 30′ placed on the guiding structure 34 (step 102). Therefore, the floating member 38 is shrunk by the compressing and the guiding structure 34 moves down with the image sensor 30′ (it means that the height of the guiding structure 34 in the test device (or socket 31′) is decreased). It results in that the top tips of the test probes 36 protrude from the top surface of the guiding structure 34 through the second holes 35 and the top tips of the test probes 36 are contacted and electrically connected with the lead 32. By this way, an electronic signals delivering path between the test circuit board 42 and the image sensor 30′ is created without any signals transferring device and any extra probe. After that, the electronic signals for testing are inputted from the test circuit board 42 and then, they are transferred to the image sensor 30′ for testing the image sensor 30′ (step 104). And compressing or pressing the top surface of the test device, the guiding structure 34 or the image sensor 30′ held on the guiding structure 34 until the test is finish for maintaining the test probes 36 to be contacted and electrically connected with the test circuit board 42 and the image sensor 30′ to form the electronic signals delivering path. And a light emitted from the light source 48 and transmitted to the light active surface 33 through the first opening 46 of the base 40 and the second opening 44 of the guiding structure 34. And then, the pressure performed on the top surface of the test device, the guiding structure 34 or the electronic element package 30 held on the guiding structure 34 is released or removed (step 106). Therefore, the floating member 38 is restored because of the releasing of the pressure and the elastic characteristics of the floating member 38. And then, the guiding structure 34 is raised to the original position in the socket 31′ before compressing, and the top tips of the test probe 36 are separated from the leads 32 and received into the second holes 35. The test probes 36 are received into test device (or the socket 31) again. Finally, the image sensor which has been tested is picked up (step 108), and then, it is placed on a container and repeating steps 100-108 to test the other image sensors until all image sensors have been tested.

In the socket, the test device and the test method of the present invention for the testing electronic element packages with leads or for the testing image sensors with leads, the test probes are received into the first holes of the base and the second hole of the guiding structure. Therefore, before a pressure is performed on the top surface of the guiding structure, the test probe do not protrude from the top surface of the guiding structure for maintaining the the top surface of the guiding structure to be even. By the way, the deflective placing of the electronic element packages or the image sensors, which is caused by the protrusion of the test probes, can be prevented and the test probes can be prevented from damage and crooked. Therefore, the frequency of changing the test probes is decreased and the test rate is improved. Besides, in the present invention, a floating member with elastic and restoring characteristics is disposed between the base and the guiding structure for control the formation and the removing of the electronic signals delivering path between the test circuit board and the electronic package (or the image sensor). The test probes are used to be the signals transferring media directly without any signals transferring device and any extra probe. Therefore, the electronic signals delivering path is shortened and the accuracy and reliability of the test process is improved.

What is claimed is:

1. A socket for testing electronic element packages with leads, comprising:
a base having a plurality of first holes;
a guiding structure for guiding and holding a electronic element package with leads to be tested, wherein guiding structure has a plurality of second holes and each of said second holes is corresponded to one of said first holes; and
at least one floating member disposed between said base and said guiding structure.

2. The socket of claim 1, wherein said guiding structure further comprises a cavity for holding an electronic element package with leads.

3. The socket of claim 1, further comprising a plurality of test probes

4. The socket of claim 3, wherein each of said test probes is received into one of said first holes and one of said second holes corresponded to said first hole, and each of said test probes does not protrude from the top surface of said guiding structure before testing.

5. The socket of claim 1, wherein said floating member is an elastic material, and when an electronic element package with leads is tested, said floating member is shrunk by compressing for protruding said test probes from the top surface of said guiding structure to contact the electronic element package with leads.

6. The socket of claim 1, wherein said floating member is a spring.

7. A test device for testing electronic element packages with leads, comprising:
a test circuit board having test circuits; and
a socket disposed on said test circuit board wherein said socket comprises:
a base having a plurality of first holes;
a guiding structure for guiding and holding a electronic element package with leads to be tested, wherein guiding structure has a plurality of second holes and each of said second holes is corresponded to one of said first holes;
at least one floating member disposed between said base and said guiding structure; and
a plurality of test probes, wherein said a plurality of test probes are electrically connected with an electronic element packages with leads when said socket is compressed.

8. The test device of claim 7, wherein said guiding structure further comprises a cavity for holding an electronic element package with leads.

9. The test device of claim 7, wherein each of said test probes is received into one of said first holes and one of said second holes corresponded to said first hole, and each of said test probes does not protrude from the top surface of said guiding structure before testing.

10. The test device of claim 7, wherein said floating member is an elastic material, and when an electronic element package with leads is tested, said floating member is shrunk by compressing for protruding said test probes from the top surface of said guiding structure to contact the electronic element package with leads.

11. The test device of claim 7, wherein said floating member is a spring.

12. The test device of claim 7, wherein said electronic element package with leads is image sensor with leads.

13. The test device of claim 12, wherein said base further comprises a first opening for passing a light through said first opening to test said image sensor with leads.

14. The test device of claim 13, wherein said guiding structure has a second opening corresponded to said first opening for passing a light through said first opening of said base and said second opening of said guiding structure to test said image sensor with leads.

15. The test device of claim 7, further comprising a pressing plate disposed above said test device, wherein said pressing plate is fixed on said base by screws for pressuring said socket or a electronic element packages with leads on said base.

16. A test method for testing image sensors with leads, comprising
placing a image sensor on a guiding structure of a socket, wherein a plurality of test probes received into said guiding structure and said socket;
compressing said socket for protruding said test probes from the top surface of said guiding structure to contact said electronic element package with leads; and
inputting a electronic signal through said test probes for testing said electronic element package with leads.

17. The test method of claim 16, wherein said socket further comprises:
a base having a plurality of first holes;
a guiding structure for guiding and holding a electronic element package with leads to be tested, wherein guiding structure has a plurality of second holes and each of said second holes is corresponded to one of said first holes;
at least one floating member disposed between said base and said guiding structure; and
a plurality of test probes, wherein said a plurality of test probes are electrically connected with an electronic element packages with leads when said socket is compressed.

18. The test method of claim 17, wherein said compressing said socket step is to compress said floating member for dropping off said guiding structure and for protruding said test probes from the top surface of said guiding structure to contact the electronic element package with leads.

19. The test method of claim 17, wherein said base has a first opening and said guiding structure has a second opening corresponded to said first opening for passing a light through said first opening and said second opening to test said image sensor with leads.

20. The test method of claim 19, further comprising transmitting a light through said first opening and said second opening to test said image sensor with leads.

21. The test method of claim 19, further comprising releasing said socket to be restored said floating member for raising said guiding structure to the original position before compressing, and then receiving said test probes into said guiding structure again.
